(19) United States
(12) Patent Application Publication
(10) Pub. No.: US 2009/0285014 A1
(43) Pub. Date: Nov. 19, 2009

(54) INTEGRATED CIRCUIT AND METHOD FOR SWITCHING A RESISTIVELY SWITCHING MEMORY CELL

(75) Inventors: Petra Majewski, Muenchen (DE); Jan Boris Philipp, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 12/120,674

(22) Filed: May 15, 2008

(51) Int. Cl. G11C 11/00

(52) U.S. Cl. 365/163; 365/148

(57) ABSTRACT

An integrated circuit and method for switching a resistively switching memory cell. One embodiment provides an initial pulse and at least one escalated pulse in case the memory cell did not switch.

### BACKGROUND

The invention relates to resistively switching memory cells and a method for switching the cells.

In resistively switching memory cells the information is stored in a memory element switching between two states. In a first state the memory element may have a high resistivity, i.e. a low conductivity, and a lesser resistivity, i.e. a higher conductivity, in a second state. The information of a bit accordingly can be assigned to a memory cell including a resistively switching memory element, wherein the state of the cell reflects the value of the bit. For example, a memory element state of low resistivity, i.e. high conductivity, may be assigned a logic 1 and a memory element state of high resistivity, i.e. low conductivity, may be associated with logic 0.

For reading a resistively switching memory cell the resistance of the memory element is sensed, i.e. the conductivity is sensed. This can be achieved for example by applying a predefined voltage to the cell and sensing the amplitude of the current flowing through the cell.

Resistively switching memory elements incorporating a transition from a metal to an oxide, binary-TMO (Transition Metal Oxide), have been described for example in “Highly Scalable Non-volatile Resistive Memory using Simple Binary Oxide Driven by Asymmetric Unipolar Voltage Pulses” by I. G. Baek, IEDM Tech December 2004. Applicable materials may be perovskite oxides such as Cr-doped SrTi(Zr)O₃ or Pr_{0.7}Ca_{0.3}MnO₃ or PbZr_{0.52}Ti_{0.48}O₃ or binary oxides such as the nominal compositions NiOₓ or Fe₂O₃ or CoO. Memory elements of these compounds form filamentary current paths, which may be reversibly switched on or off by an appropriate electrical pulse.

Applying electrical pulses to these memory elements thus can control the electrical characteristics of this type of memory elements. For example, when operating a current pulse is required to switch the memory element from a low resistance, i.e. conducting, state to high resistance state and a current-limited voltage pulse switches the memory element back to the conducting state. A switching of a memory element from high resistance to low resistance may be also referred to the memory cell is being set. Vice versa an opposite switching of a cell, i.e. from a low resistance to high resistance, may be referred to the memory cell then being reset.

An ever-challenging problem is to improve memory to higher switching speeds and higher reliability. In one embodiment, when switching a TMO cell from high to low resistance a short pulse of high voltage but low current is required. In case that the voltage or current amplitude of the applied pulse is too high there is a risk to damage the memory cell thus making it inoperable, i.e. unswitchable. Accordingly an improved method for switching TMO memory cells fast and reliably and an adapted memory device are desired.

### SUMMARY

One embodiment provides a method and an integrated circuit for switching a resistively switching memory cell from an initial resistivity state to the opposite resistivity state by applying an initial electrical pulse to the memory cell, sensing the resistivity of the memory cell and applying an escalated electrical pulse to the memory cell in case the memory cell did not switch to the opposite resistivity state. The processes of sensing the resistivity and applying an escalated pulse are repeated sequentially until the memory cell has switched to the opposite resistivity state.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic of a memory device including TMO memory cells.

FIG. 2 schematically illustrates a TMO memory element.

FIG. 3 illustrates a flow diagram of a method for switching a memory cell from high to low resistivity.

FIG. 4 illustrates a test chart of three switch operations of a memory cell from high to low resistivity.

FIG. 5 illustrates a flow diagram of a method for switching a memory cell from low to high resistivity.

FIG. 6 illustrates a test chart of three switch operations of a memory cell from low to high resistivity.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

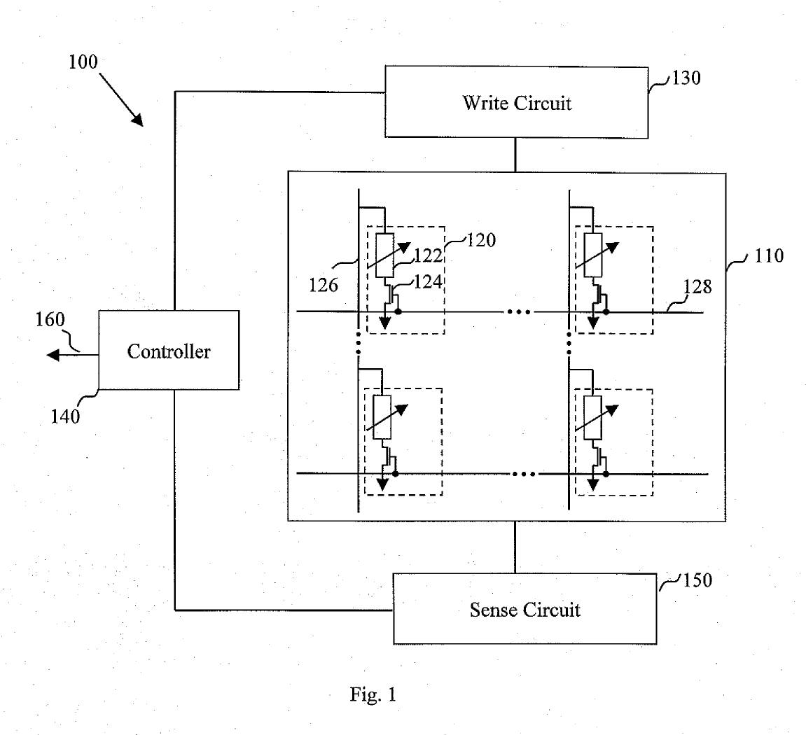

FIG. 1 illustrates a memory device 100 including an array 110 of memory cells, wherein the array includes a plurality of memory cells. Each of the exemplified memory cells 120 includes a memory element 122 and in series a selection device 124, which may be a transistor as illustrated or a diode.

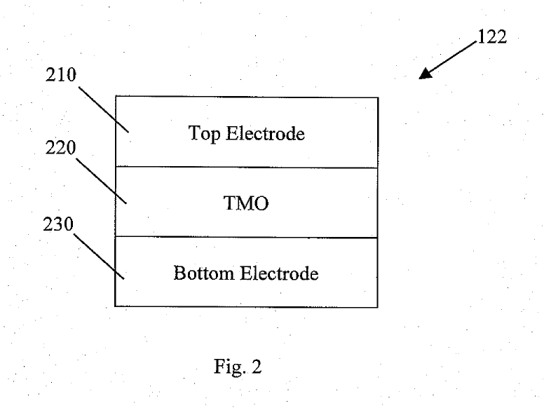

As schematically illustrated in FIG. 2 a memory element 122 basically includes two electrodes, i.e. a top electrode 210 and a bottom electrode 230, sandwiching a layer of TMO material 220. Electrodes 210 and 230 preferably are of metal or any other suitable conducting material and may have any suitable shape.

Referring back to FIG. 1, memory cell 120 is coupled with its one end to a first selection line 126, for example a bit line, and to a second selection line 128, e.g., a word line. That is, as illustrated in the illustrated embodiment, memory element 122 is coupled with its one end to first selection line 126 and with its other end to selection device 124, for example to a source/drain of a selection transistor, which in turn is coupled with its gate to second selection line 128. The residual source/drain of the selection transistor is coupled to ground potential. For selecting one of the plurality of memory cells appropriate voltages are applied to a pair of a first 126 and a second selection line 128, i.e. a bit line and a word line, such that the selection transistor 124 coupled to the second selection line is switched into the ON state and a current may flow from the selected first selection line through the memory element and the selection device to ground. That is each of the memory cells in array 110 can be selected for operation by applying appropriate voltages to a selected pair of a first and second selection line.

The voltages applied to a pair of selection lines are produced by write circuit 130, which is coupled to array 110 and capable of providing voltages to each pair of a first and second selection line. Write circuit 130 is thus communicatively connected with controller circuit 140, which in turn is connected to sense circuit 150 and to any computer or digital processing system, i.e. any host, via data bus 160 for receiving and transmitting control information and data. In this way any computer system may include a host and a memory device communicatively coupled to the host.

For reading data from memory array 110 the controller 110 receives appropriate control information via bus system 160 and accordingly instructs sense circuit 150, which is coupled to first and second selection lines of array 110, to apply appropriate voltages to lines for detecting the resistivity of memory cells and thus to read data, which is then forwarded to controller 140.

For writing data to memory controller 140 receives the appropriate data via bus 160. Controller 140 accordingly forwards the data to be stored in memory to write circuit 130 and controls write circuit 130 to write the supplied data.

Writing data to a memory cell either means to write a memory cell, i.e. to switch the memory element from any previous resistivity state, i.e. in one embodiment to set a memory element from high resistivity to a low resistivity state, or means to reset a memory element from low resistivity to high resistivity.

For switching a memory element from high resistivity to low resistivity a method of applying an initial suitable electrical pulse is applied to the memory element, sensing and comparing the resistivity value of the memory element with a threshold and applying another electrical pulse of higher voltage to the memory element in case the sensed resistivity value is above the threshold.

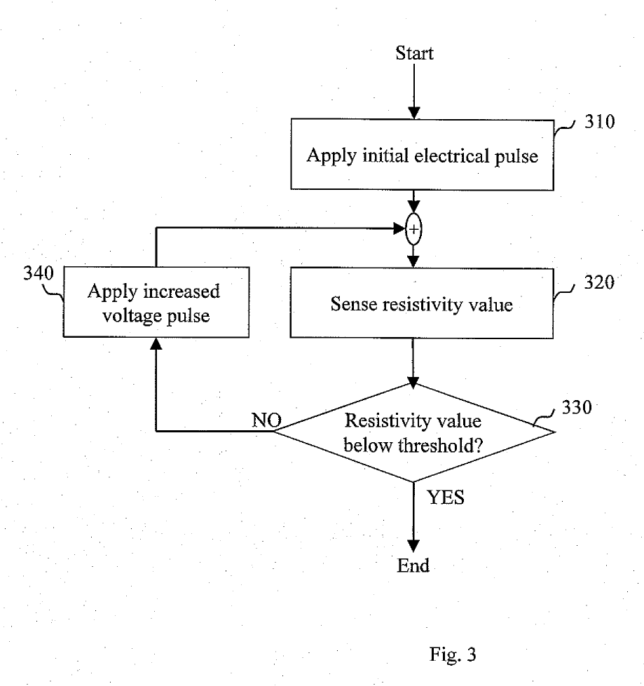

The flowchart illustrated in FIG. 3 illustrates the processes for switching a memory cell to low resistivity. Starting at process 310 an initial electrical pulse of predefined voltage and duration is applied to the memory cell, which can be achieved by applying appropriate voltages to the selection lines. Note that in a variation of the below explained sequence of processes the first process may be to sense the resistivity of a cell to check the initial resistivity, such that the process may stop if the measured value already is below the threshold.

Next, in process 320, the resistivity value of the memory element is sensed, which may be achieved, for example, by applying suitable, predefined voltages to the pair of selection lines, wherein the sensing voltage applied to the first selection line is lower than the voltage applied for switching the cell.

In 330, the sensed resistivity value is compared to a threshold for verifying that the value is below or above the threshold, wherein the threshold is predefined and defines the upper maximum value of a low resistivity state.

The process of setting the memory element to low resistivity ends, if the sensed resistivity value is below the predefined threshold.

Otherwise, i.e. if the comparison of the sensed resistivity value reveals the value being above the threshold, an escalated electrical pulse of the same duration but of higher voltage as in the previous process of applying a voltage is applied to the memory cell, see 340. The voltage of the applied pulse thus increases in every loop run. The higher voltage of this escalated electrical pulse can be achieved by increasing the voltage applied to the bit line, i.e. the first selection line.

After the escalated pulse has been applied in 340 the process of switching the memory element to low resistivity continues with 320, i.e. the resistivity of the memory element is sensed again and then, i.e. in 330, compared again to the threshold. This sequence of applying an escalated electrical pulse, subsequently sensing the resistivity value and comparing the sensed resistivity value to the threshold ends if the resistivity value falls below the threshold, wherein the voltage of the electrical pulse is increased stepwise in each repetition.

Although the memory cell should be switched to low resistivity the process may also provide for situations in which the repetition sequence ends without having switched the memory cell to low resistivity. For example, the repetition may also end if a predetermined number of repetitions is exceeded even if the sensed resistivity value of the memory cell exceeds the threshold. For this purpose a counter initially set to zero for example when executing the first method process is incremented in each repetition. When the counter exceeds a predefined maximum of repetitions, then the process of switching the memory cell to low resistivity may end and an appropriate error handling may be performed. In one example an error can be signaled to the controller, which in turn signals the failure of the write action to the digital signal processing.

In a variation the sequence of applying escalated electrical pulses may stop in case that a predefined maximum voltage of the electrical pulse has been sent. In case that the maximum voltage pulse did not switch the memory cell to low resistivity an appropriate error handling may be performed, which may include the option of storing the data in another memory cell.

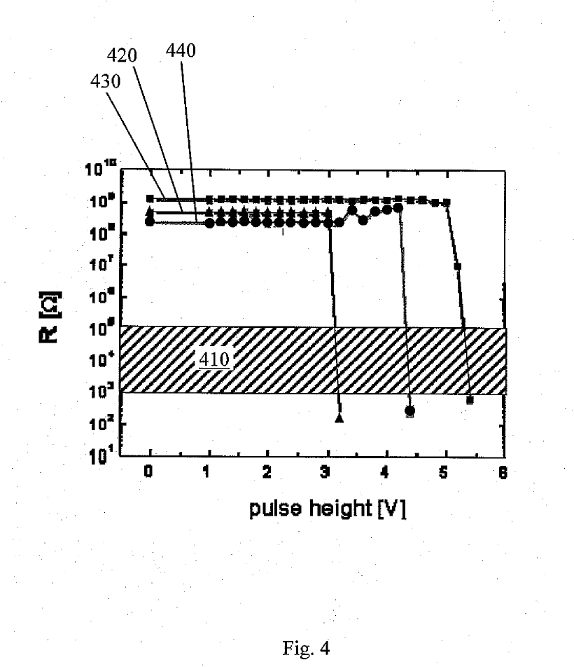

FIG. 4 illustrates a test chart produced when switching a TMO memory cell from high to low resistivity.

The chart indicates the sensed resistivity of a memory cell versus the voltage of pulses applied to the cell, i.e. the x-axis indicates the voltage of the pulses whereas the y-axis references the sensed resistivity of the memory cell after applying the pulse.

For the memory cell used in this configuration a resistivity above 100,000Ω indicates a high resistivity state of a cell and a resistivity below 1,000Ω indicates a state of low resistivity. Shaded range 410, i.e. a resistivity between 1,000Ω and 100,000Ω, accordingly indicates undesirable resistivity values.

The chart illustrates three switch operations of one cell from high to low resistivity, wherein the first operation 420 uses triangles to indicate the values of measured resistivity, the second switch operation 430 uses squares and the third operation 440 employs circles.

The first measured resistivity value in all switch operations is at 0 Volts indicating the initial resistivity value of the memory cell, which is around 10⁸Ω for the first switching operation 420. Then a series of voltage pulses is applied to the cell starting at 1.0 Volt, wherein the amplitude is increased by 0.2 Volt for each subsequent pulse. With regard to the flow chart of FIG. 3, the voltage of the pulse is increased by 0.2 Volt at 340. As illustrated the resistivity value of the memory cell nearly remains at the initial value until again in 340 a voltage pulse of 3.0 Volts is applied to the cell. In the subsequent step, i.e. 320 the resistivity value is sensed. The process decides at 330 that the sensed value is still above the threshold of 10³Ω, such that another pulse of increased voltage, i.e. of 3.2 Volts, is applied to the memory cell, such that when executing steps method steps 320 and 330 respectively it is found that the sensed resistivity value is below the desired threshold and the sequence as of FIG. 3 is ended.

In switching operation 420 the voltage of the applied pulses was increased from 1.0 Volt to 3.2 Volts with a width of 0.2 Volts, wherein between the application of two consecutive pulses the actual resistivity value has been sensed and a decision was made to increase the voltage of the pulse.

As illustrated switching operations 430 and 440 may start at different initial resistivity values. Also the switching from high to low resistivity was affected at different voltages, wherein switching operation 430 started at a higher initial resistivity value and needed a higher voltage pulse for switching than operation 440.

The variation of the initial resistivity sensed at the beginning of a switching operation may result from various factors. The resistivity of a single cell may vary for example due to temperature changes or the time between two switching operation or the electric pulse sent through the memory element in the last operation. However the proposed method for switching a cell is flexible to provide an electrical pulse of suitable voltage to switch the cell from high to low resistivity.

In the three illustrated switching operations only the amplitude of the applied electrical pulse was changed, all other parameters of the pulse were maintained constant. In particular the applied electrical pulse was a trapezoidal pulse with defined slew rate of the leading and trailing edges (pulse parameters defined at the pulse generator: width of 3.03 ns, the width includes a leading edge of 2 ns. The pulse trail was set to 2 ns), such that the duration is adapted to form one or more conducting filaments in the TMO but not too many.

In variations of the proposed method the pulse shape may be different from a rectangular or trapezoidal pulse. In particular due to the frequency spectrum comprised in a rectangular pulse the leading edge of a rectangular pulse may include a voltage peak where the actual voltage exceeds the desired voltage. Accordingly other pulse shapes of limited frequency spectrums may be used, for example a pulse having the shape of a triangle or a rounded triangle or of a Gaussian function.

For switching a memory cell from low to high resistivity a current pulse is required, wherein it is apparent that the high current due to the low resistivity affects a comparatively low voltage across the memory element. However a current pulse of too high current amplitude may affect a high voltage across the memory element such that the high voltage which drops over the memory element after it switched to the high resistive state may cause an instant switching back to the low resistive state during the same pulse, hence it may prevent a switch to high resistivity and may damage the memory element due to the unintended set without proper set current limitation. Accordingly the amplitude of the applied current must not exceed a limit, which depends on the characteristics of the employed TMO material.

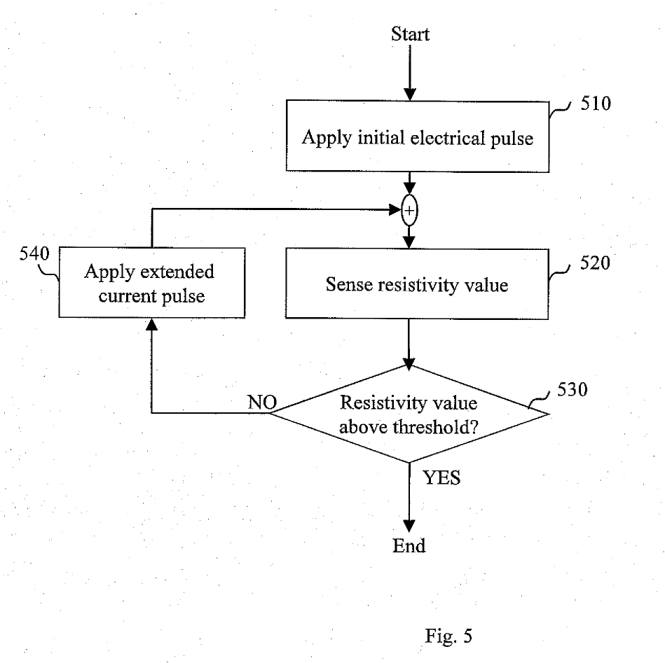

The method for switching a memory cell from low to high resistivity in some aspects is similar to that described above. Referring to FIG. 5 the method may start at 510 with applying an initial electrical pulse, which in this case is a current pulse of low voltage and predefined characteristics. Subsequently, i.e. when the current pulse has been applied, the resistivity of the memory cell is sensed in 520. In case the sensed resistivity is below a threshold, confer 530, then another current pulse of equal current amplitude but extended duration is applied to the memory cell in 540. The process of switching the memory cell from low to high resistivity continues with 520, i.e. sensing the resistivity of the memory cell after applying a current pulse. This sequential repetition of sensing the resistivity and applying a current pulse of extended duration continues until a predefined threshold indicating a high resistivity of the memory cell is exceeded. Note that in a variation of the above-explained sequence of processes the first process may be to sense the resistivity of a cell to check the initial resistivity, such that the process may stop if the measured value already is above the threshold.

Note that the duration of the current pulse applied to the memory cell is extended in each loop run, but wherein other characteristics of the applied pulse remain constant. That is the current amplitude of the current pulse remain constant and only the duration of the pulse is escalated in each repetition.

Similar as described for switching the cell from high to low resistivity the process for switching from low to high resistivity may also provide for situations in which the loop without having switched the cell to high resistivity. For example, the loop may end in case a predetermined number of repetitions is exceeded, wherein a counter initially set to zero is incremented in each repetition. Accordingly the repetitions may end if a current pulse of maximum duration has been applied to the memory cell without affecting a switch to high resistivity. In these cases the controller may perform an appropriate error handling.

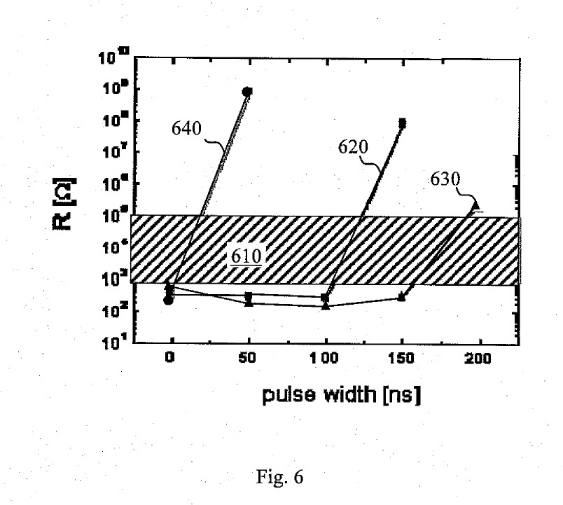

FIG. 6 illustrates a test chart of switching a memory cell from low to high resistivity, wherein a resistivity value below 1,000Ω indicates low resistivity and above 100,000Ω indicates a high resistivity value. Accordingly shaded range 610 indicates the undesired range of values.

The chart illustrates the sensed resistivity of the cell in Ω on the y-axis in logarithmic scale versus the width of the applied current pulse in nano seconds on the x-axis.

The sensed resistivity values of the three switching operations 620, 630 and 640 are indicated by markers i.e. squares in the first switching operation, triangles in the second and circles in the third. The initial resistivity values of the memory cell are in a range between 10²Ω and 10³Ω as indicated by the markers at a pulse width of 0 ns. Note that the data is of the same memory cell described for the set operations in FIG. 4.

As mentioned above only the pulse duration, i.e. the pulse width is escalated in each repetition, whereas all other pulse parameters are maintained constant. The pulses applied in the test were of trapezoidal pulse shape with defined leading and trailing edge slew rate (the width includes a lead-time of 50 ns. The pulse trail was set to 50 ns. Thus for the special case of a pulse width of 50 ns, the resulting shape of the pulse is triangular) having amplitude of 1.6 Volts.

In the first switching operation 620 a first current pulse of 50 ns width followed by a second pulse of 100 ns and a third pulse of 150 ns duration is applied to the memory cell, wherein the last pulse switches the memory cell to a resistivity value of around 10⁸Ω, which is well above shaded area 610 and thus recognized as high resistivity. Accordingly this switching process is successful using the third pulse of 150 ns duration. Starting from duration of 50 ns the pulse width, i.e. the duration of the applied pulses, is escalated by 50 ns in each repetition.

In the second switching operation 630 the fourth pulse having a pulse width of 200 ns switches the cell to a resistivity value of around 3·10⁵Ω, which is above shaded area 610.

In the third switching operation 640 the cell switches to a resistivity of around 10⁹Ω upon applying the initial current pulse of 50 ns pulse width, such that there was no application of a second, escalated pulse.

As illustrated in the first and second switching operation the applied pulse was escalated in each repetition by escalating the width of the applied pulse, i.e. the duration of the applied current pulse. Starting from an initial value of 50 ns the pulse width was escalated by 50 ns in each repetition, such that the width of the second applied pulse was 100 ns, the width of the third pulse was 150 ns etc.

Similar as described for switching from high to low resistivity in variations of the proposed switching method the pulse shape of the applied current pulse for switching a memory cell form low to high resistivity may deviate from a trapezoidal pulse. That is in variations current pulses having the shape of for example a rectangle or a triangle or a rounded triangle or of a Gaussian function may be used.

Also the process width in escalating the pulse width may be varied for example such that the process width may be decreased or increased. In one embodiment the process width may start at an initial pulse width of 50 ns, which then may be increased in a first repetition by 40 ns, in a second repetition by another 30 ns and further on by further decreased or constant steps in order to slowly approach a maximum pulse width. Vice versa in other embodiments the escalation of the initial pulse width may start from a small value and may end in a predefined maximum process width, such that the pulse width is increased exponentially.

In this way a method and an electrical circuit are proposed for switching at least one resistively switching memory cell from an initial resistivity state to the opposite resistivity state. The initial resistivity state may either be low or high resistivity, such that the opposite resistivity state is the state of high or low resistivity respectively. In a first process an initial electrical pulse is applied to the memory cell, wherein the electrical pulse may have a predefined voltage and pulse width and one of the above mentioned pulse shapes. After the initial pulse is applied the resistivity value of the memory cell is sensed and compared to a predefined threshold value. In case the threshold was exceeded in a switch operation from low to high resistivity the method ends, otherwise an electrical pulse of escalated pulse width is applied to the memory cell. In case of a switch operation from high to low resistivity the method checks if the sensed resistivity is below a predefined, different threshold resistivity. If the cell did not switch to a resistivity below the threshold, then another pulse of escalated amplitude is applied to the cell. For either switching operation a sequence of sensing the resistivity and applying another escalated pulse is repeated, wherein in each repetition the pulse is more escalated, until the cell has switched as desired or until one of the above-mentioned loop terminating conditions is reached.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for operating an integrated circuit including switching a resistively switching memory cell from an initial resistivity state to the opposite resistivity state, comprising:
applying an initial electrical pulse to the memory cell; and
sensing a resistivity of the memory cell and applying an escalated electrical pulse to the memory cell, until the memory cell has switched to the opposite resistivity state.

2. The method of claim 1, where in case the memory cell did not switch to the opposite resistivity state after a predefined maximum escalated electrical pulse is applied, performing an error handling.

3. The method of claim 1, comprising escalating the voltage amplitude of the electrical pulse for switching the memory cell from high to low resistivity.

4. The method of claim 3, comprising escalating the voltage amplitude by a predefined voltage step.

5. The method of claim 4, comprising maintaining a constant width of the electrical pulse.

6. The method of claim 1, comprising escalating the pulse width of the electrical pulse for switching the memory cell from low to high resistivity.

7. The method of claim 6, comprising escalating the pulse width by a predefined duration.

8. The method of claim 6, comprising maintaining a constant amplitude of the electrical pulse.

9. The method of claim 1 further comprising:
initially sensing the resistivity value of the memory cell executed prior to applying the initial electrical pulse.

10. The method of claim 1, wherein the memory cell comprises a Transition-Metal-Oxide (TMO) memory element.

11. An integrated circuit comprising:
at least one resistively switching memory cell; and
means for applying an electrical pulse to the memory cell and sensing the resistivity of the memory cell for switching the cell from an initial resistivity state to the opposite resistivity state, the electrical circuit comprising:
applying an initial electrical pulse to the memory cell;
sensing the resistivity of the memory cell;
applying an escalated electrical pulse to the memory; and
repeating until the memory cell has switched to the opposite resistivity state.

12. The integrated circuit of claim 11 further configured to perform an error handling in case the memory cell did not switch to the opposite resistivity state after a predefined maximum escalated electrical pulse is applied.

13. The integrated circuit of claim 11, comprising wherein the circuit is configured to escalate the voltage amplitude of the applied electrical pulse for switching the memory cell from high to low resistivity.

14. The integrated circuit of claim 13, comprising wherein the circuit is configured to escalate the voltage amplitude by a predefined voltage step.

15. The integrated circuit of claim 14, comprising wherein the circuit is configured to maintain the width of the electrical pulse constant.

16. The integrated circuit of claim 11, comprising wherein the circuit is configured to escalate the pulse width of the applied electrical pulse for switching the memory cell from low to high resistivity.

17. The integrated circuit of claim 16, comprising wherein the circuit is configured to escalate the pulse width by a predefined duration.

18. The integrated circuit of claim 11, comprising wherein the circuit is further configured for sensing the resistivity of a memory cell prior to applying the initial electrical pulse.

19. The integrated circuit of claim 11, comprising wherein the resistively switching memory cell comprises a Transition-Metal-Oxide memory element.

20. An integrated circuit comprising:
an array of resistively switching memory cells;
a write circuit configured for applying an electrical pulse to a selected memory cell; and
a sense circuit for sensing the resistivity of the memory cell;
wherein for switching the cell from an initial resistivity state to the opposite resistivity state, the integrated circuit comprising:
applying an electrical pulse to the memory cell;
sensing the resistivity of the memory cell; and
repeating sequentially at least until the memory cell has switched to the opposite resistivity state.

21. The integrated circuit of claim 20, wherein the resistively switching memory cell comprises a Transition-Metal-Oxide memory element.

22. A system comprising:
a host; and
a memory device communicatively coupled to the host, the memory device comprising:
an array of resistively switching memory cells;
a write circuit configured for applying an electrical pulse to the selected memory cell; and
a sense circuit configured for sensing the resistivity state of the memory cell,
wherein for switching the cell from an initial resistivity state to the opposite resistivity state, the memory device comprising:
applying an initial electrical pulse to the memory cell;
sensing the resistivity of the memory cell;
applying an escalated electrical pulse to the memory cell; and
repeating sequentially at least until the memory cell has switched to the opposite resistivity state.

23. The system of claim 22, comprising wherein the voltage amplitude is escalated by a predefined voltage process for switching the memory element from the high to the low resistivity state, and the width of the electrical pulse is escalated by a predefined duration for switching the memory element from the low to the high resistivity state.

24. The system of claim 22, wherein the resistively switching memory cell comprises a Transition-Metal-Oxide memory element.
